(19) United States
(12) Patent Application Publication
(10) Pub. No.: US 2018/0315781 A1
(43) Pub. Date: Nov. 1, 2018

(54) COMPLEMENTARY THIN FILM TRANSISTOR AND MANUFACTURING METHOD THEREOF, AND ARRAY SUBSTRATE

(71) Applicant: BOE Technology Group Co., Ltd., Beijing (CN)

(72) Inventors: Xiaolong He, Beijing (CN); Dongsheng Li, Beijing (CN); Shengguang Ban, Beijing (CN)

(73) Assignee: BOE TECHNOLOGY GROUP CO., LTD.

(21) Appl. No.: 15/834,198

(22) Filed: Dec. 7, 2017

(30) Foreign Application Priority Data
Apr. 26, 2017 (CN) 201710281639.5

(51) Int. Cl. H01L 27/12; H01L 21/02

(52) U.S. Cl. CPC H01L 27/1274; H01L 21/0262; H01L 27/1229; H01L 21/02532; H01L 29/78618; H01L 21/02675; H01L 21/02576; H01L 21/02579; H01L 21/02592

(57) ABSTRACT

The present disclosure relates to a complementary thin film transistor, a manufacturing method thereof, and an array substrate in the field of semiconductors. The method includes: forming a first semiconductor layer on an active layer pattern and patterning the first semiconductor layer to form a first ohmic contact layer; forming a second semiconductor layer on the active layer pattern and patterning the second semiconductor layer to form a second ohmic contact layer. During the process of manufacturing the complementary thin film transistor, the first semiconductor layer is formed on the active layer pattern and the first semiconductor layer is patterned to form the first ohmic contact layer. In addition, the second semiconductor layer is formed on the active layer pattern and the second semiconductor layer is patterned to form the second ohmic contact layer. Since one of the first semiconductor layer and the second semiconductor layer is an N-type semiconductor layer and the other is a P-type semiconductor layer, doping is not needed and thus the manufacturing cost of the CMOS TFT may be reduced.

### CROSS-REFERENCE TO RELATED APPLICATION

This application claims priority to Chinese Patent Application No.: 201710281639.5, filed with the State Intellectual Property Office on Apr. 26, 2017 and titled “Complementary Thin Film Transistor and Manufacturing Method thereof, and Array Substrate”, which is incorporated herein by reference in its entirety.

### TECHNICAL FIELD

The present disclosure relates to the field of semiconductors, and more particularly to a complementary thin film transistor, a manufacturing method thereof, and an array substrate.

### BACKGROUND

Generally, both a liquid crystal display and an organic light-emitting diode display use a TFT (Thin Film Transistor) for making the drive circuit. In the display, at least one TFT is arranged for each sub-pixel unit in a pixel unit, and the sub-pixel unit is controlled to be lit or extinguished by the on or off state of the TFT. For example, in an OLED display, each pixel unit generally includes three sub-pixel units, each comprising one OLED. And at least one TFT is arranged for each OLED. When the TFT is turned on, the corresponding OLED will be lit. Otherwise, the corresponding OLED will be extinguished.

At present, usually a Complementary Metal Oxide Semiconductor (CMOS) TFT is used to reduce the power consumption of a display. In other words, a complementary TFT is used to drive the OLED to emit light. One CMOS TFT consists of one P-type metal oxide TFT and one N-type metal oxide TFT.

In the current manufacturing process of a CMOS TFT, usually a non-doped active layer is formed first, and a portion of the non-doped active layer is doped to form ohmic contact layers on the active layer. A P-type ohmic contact layer is needed in a P-type metal oxide TFT, and an N-type ohmic contact layer is needed in an N-type metal oxide TFT. Since the dopants for the two ohmic contact layers are different, masks needs to be disposed separately for doping. For example, a mask may be disposed on the active layer corresponding to the N-type metal oxide TFT to dope the active layer corresponding to the P-type metal oxide TFT to form a P-type ohmic contact layer. Then a mask is disposed on the active layer corresponding to the P-type metal oxide TFT to dope the active layer corresponding to the N-type metal oxide TFT to form an N-type ohmic contact layer. Two times of doping are required during the manufacturing process. As the doping process has high requirements and the doping equipment is complex and expensive, the manufacturing cost of the CMOS TFT is relatively high.

### SUMMARY

The present disclosure provides a complementary thin film transistor, a manufacturing method thereof, and an array substrate.

In an aspect, the present disclosure provides a method for manufacturing a complementary thin film transistor. The method includes: forming a first semiconductor layer on an active layer pattern, and patterning the first semiconductor layer to form a first ohmic contact layer on a first active layer, the active layer pattern comprising the first active layer and a second active layer which are arranged in the same layer at an interval; forming a second semiconductor layer on the active layer pattern, and patterning the second semiconductor layer to form a second ohmic contact layer on the second active layer. One of the first semiconductor layer and second semiconductor layer is an N-type semiconductor layer, and the other is a P-type semiconductor layer.

In some embodiments, before forming the first semiconductor layer on the active layer pattern and forming the second semiconductor layer on the active layer pattern, the method further includes: forming a gate electrode layer pattern on a basal substrate, the gate electrode layer pattern including a first gate electrode and a second electrode arranged at an interval; forming a gate electrode insulating layer on the gate electrode layer pattern; and forming the active layer pattern on the gate electrode insulating layer. The first active layer is disposed on the first gate electrode and the second active layer is disposed on the second gate electrode.

In some embodiments, after forming the active layer pattern on the gate electrode insulating layer, the method further includes: forming a barrier layer pattern on the active layer pattern. The barrier layer pattern includes a first barrier layer and a second barrier layer. The first barrier layer is disposed on the first active layer and the orthographic projection of the first barrier layer on the basal substrate is within or completely overlaps with the orthographic projection of the first active layer on the basal substrate. The second barrier layer is disposed on the second active layer and the orthographic projection of the second barrier layer on the basal substrate is within or completely overlaps with the orthographic projection of the second active layer on the basal substrate.

In some embodiments, the thickness of the first barrier layer is 1,000-2,000 angstrom, and the thickness of the second barrier layer is 1,000-2,000 angstrom.

In some embodiments, the method further includes: forming a source-drain electrode pattern on the first ohmic contact layer and second ohmic contact layer. The source-drain electrode pattern includes a first source electrode, a first drain electrode, a second source electrode and a second drain electrode. The first source electrode and the first drain electrode are respectively connected to the first ohmic contact layer, and the second source electrode and the second drain electrode are respectively connected to the second ohmic contact layer.

In some embodiments, forming the source-drain electrode pattern on the first ohmic contact layer and second ohmic contact layer includes: forming a source-drain electrode metal layer on the first ohmic contact layer and second ohmic contact layer; and patterning the source-drain electrode metal layer, the first ohmic contact layer and the second ohmic contact layer so that the first source electrode, the first drain electrode, the second source electrode and the second drain electrode are formed, the first ohmic contact layer is divided into a first sub-layer and a second sub-layer which are separated from each other, and the second ohmic contact layer is divided into a first sub-layer and a second sub-layer which are separated from each other. The first source electrode is disposed on the first sub-layer of the first ohmic contact layer, the first drain electrode is disposed on the second sub-layer of the first ohmic contact layer, the second source electrode is disposed on the first sub-layer of the second ohmic contact layer, and the second drain electrode is disposed on the second sub-layer of the second ohmic contact layer.

In some embodiments, the method further includes: forming an insulating layer on the first ohmic contact layer, the second ohmic contact layer and the active layer pattern; and forming a gate electrode layer pattern and a source-drain electrode pattern on the insulating layer. The gate electrode layer pattern includes a first gate electrode and a second gate electrode which are arranged at an interval. The source-drain electrode pattern includes a first source electrode, a first drain electrode, a second source electrode and a second drain electrode. The first source electrode and the first drain electrode are respectively connected to the first ohmic contact layer, and the second source electrode and the second drain electrode are respectively connected to the second ohmic contact layer.

Further, forming the gate electrode layer pattern and the source-drain electrode pattern on the insulating layer includes: forming the gate electrode layer pattern on the insulating layer; forming a medium layer on the insulating layer and the gate electrode layer pattern; and forming the source-drain electrode pattern on the medium layer.

In some embodiments, before forming the first semiconductor layer on the active layer pattern and forming the second semiconductor layer on the active layer pattern, the method further includes: forming a light shielding layer pattern on the basal substrate, the light shielding layer pattern including a first light shielding layer and a second light shielding layer which are arranged at an interval; and forming the active layer pattern on the light shielding layer pattern, the first active layer being disposed on the first light shielding layer and the second active layer being disposed on the second light shielding layer.

In some embodiments, the first second active layer and the second active layer are respectively made of any of: amorphous silicon and polycrystalline silicon.

In some embodiments, when both of the first active layer and the second active layer are made of amorphous silicon, the method further includes: annealing the first active layer so that a portion of the first active layer is transformed into polycrystalline silicon, and the first ohmic contact layer is connected to the portion of the first active layer that is not annealed; and annealing the second active layer so that a portion of the second active layer is transformed into polycrystalline silicon, and the second ohmic contact layer is connected to the portion of the second active layer that is not annealed.

Further, annealing the first active layer includes: annealing the portion of the first active layer that right faces the first gate electrode in a direction perpendicular to the basal substrate; and annealing the second active layer includes: annealing the portion of the second active layer that right faces the second gate electrode in a direction perpendicular to the basal substrate.

In some embodiments, annealing of the first active layer or the second active layer is performed using excimer laser.

In some embodiments, forming the first semiconductor layer on the active layer pattern includes: when the first semiconductor layer is an N-type semiconductor layer, depositing a first semiconductor material on the active layer pattern using SiH₄, PH₃ and H₂ to form the first semiconductor layer; forming the second semiconductor layer on the active layer pattern includes: when the second semiconductor layer is a P-type semiconductor layer, depositing a second semiconductor material on the active layer pattern using SiH₄, B₂H₆ and H₂ to form the second semiconductor layer.

Alternatively, forming the first semiconductor layer on the active layer pattern includes: when the first semiconductor layer is a P-type semiconductor layer, depositing a first semiconductor material on the active layer pattern using SiH₄, B₂H₆ and H₂ to form the first semiconductor layer; and forming the second semiconductor layer on the active layer pattern includes: when the second semiconductor layer is an N-type semiconductor layer, depositing a second semiconductor material on the active layer pattern using SiH₄, PH₃ and H₂ to form the second semiconductor layer.

In some embodiments, the thickness of the first active layer is 400-600 angstrom, and the thickness of the second active layer is 400-600 angstrom.

In some embodiments, the thickness of the first ohmic contact layer is 500-1,000 angstrom, and the thickness of the second ohmic contact layer is 500-1,000 angstrom.

In another aspect, the present disclosure provides a complementary thin film transistor. The complementary thin film transistor includes: an active layer pattern, a first ohmic contact layer and a second ohmic contact layer. The active layer pattern includes a first active layer and a second active layer which are arranged in the same layer at an interval, the first ohmic contact layer is disposed on the first active layer, and the second ohmic contact layer is disposed on the second active layer.

In some embodiments, the complementary thin film transistor is of a top gate type or a bottom gate type.

In a further aspect, the present disclosure provides an array substrate. The array substrate includes the complementary thin film transistor above.

The technical solutions in the embodiments of the present disclosure may bring the following advantageous benefits: during the process of manufacturing the complementary thin film transistor, a first semiconductor layer is formed on the active layer pattern and the first semiconductor layer is patterned to form the first ohmic contact layer. In addition, a second semiconductor layer is formed on the active layer pattern and the second semiconductor layer is patterned to form the second ohmic contact layer. Since one of the first semiconductor layer and the second semiconductor layer is an N-type semiconductor layer and the other is a P-type semiconductor layer, doping is not needed and thus the manufacturing cost of the CMOS TFT may be reduced.

### BRIEF DESCRIPTION OF THE DRAWINGS

To describe the technical solutions in the embodiments of the present disclosure more clearly, the following briefly introduces the accompanying drawings required for describing the embodiments, Apparently, the accompanying drawings in the following description show merely some embodiments of the present disclosure, and a person of ordinary skill in the art may readily derive other drawings from these accompanying drawings without creative efforts.

FIG. 1 is a flow chart of a method for manufacturing a complementary thin film transistor provided in an embodiment of the present disclosure;

FIG. 2 is a flow chart of another method for manufacturing a complementary thin film transistor provided in an embodiment of the present disclosure;

FIG. 3 to FIG. 13 are schematic views of a process for manufacturing a complementary thin film transistor provided in an embodiment of the present disclosure;

FIG. 14 is a flow chart of another method for manufacturing a complementary thin film transistor provided in an embodiment of the present disclosure;

FIG. 15 to FIG. 17 are schematic views of a process for manufacturing a complementary thin film transistor provided in an embodiment of the present disclosure;

FIG. 18 is a flow chart of another method for manufacturing a complementary thin film transistor provided in an embodiment of the present disclosure;

FIG. 19 to FIG. 22 are schematic views of a process for manufacturing a complementary thin film transistor provided in an embodiment of the present disclosure.

### DETAILED DESCRIPTION

The present disclosure will be described in further detail with reference to the enclosed drawings, to clearly present the objects, technique solutions, and ad vantages of the present disclosure.

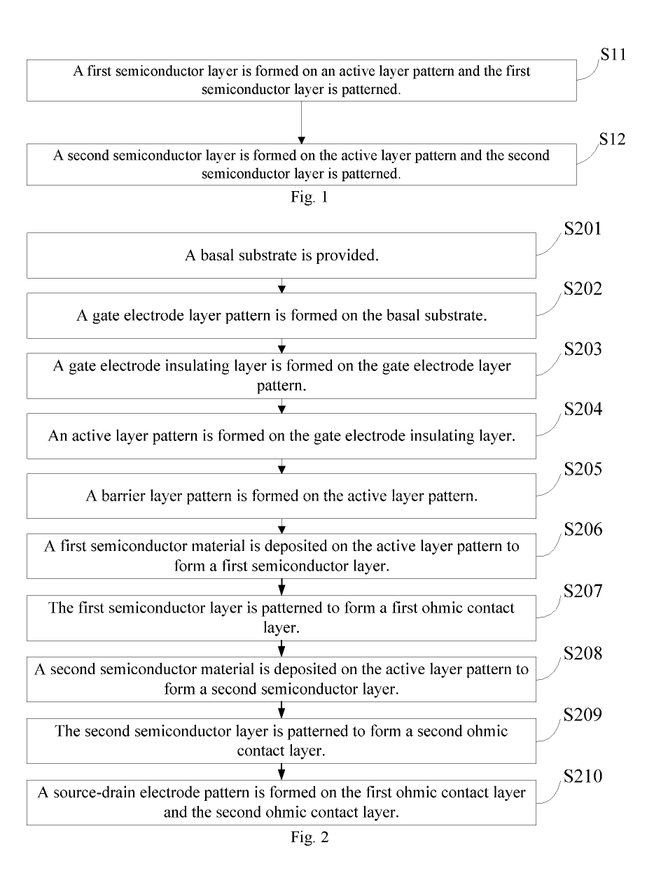

FIG. 1 is a flow chart of a method for manufacturing a complementary thin film transistor provided in the embodiments of the present disclosure. As shown in FIG. 1, the method includes:

S11: a first semiconductor layer is formed on an active layer pattern and the first semiconductor layer is patterned to form a first ohmic contact layer on a first active layer. The active layer pattern includes a first active layer and the second active layer which are arranged in the same layer and at an interval.

S12: a second semiconductor layer is formed on the active layer pattern and the second semiconductor layer is patterned to form a second ohmic contact layer on the second active layer.

One of the first semiconductor layer and the second semiconductor layer is an N-type semiconductor layer and the other is a P-type semiconductor layer.

During the process of manufacturing the complementary thin film transistor in the embodiments of the present disclosure, the first semiconductor layer is formed on the active layer pattern and the first semiconductor layer is patterned to form the first ohmic contact layer. In addition, the second semiconductor layer is formed on the active layer pattern and the second semiconductor layer is patterned to form the second ohmic contact layer. Since one of the first semiconductor layer and the second semiconductor layer is an N-type semiconductor layer and the other is a P-type semiconductor layer, doping is not needed and thus the manufacturing cost of the CMOS TFT may be reduced.

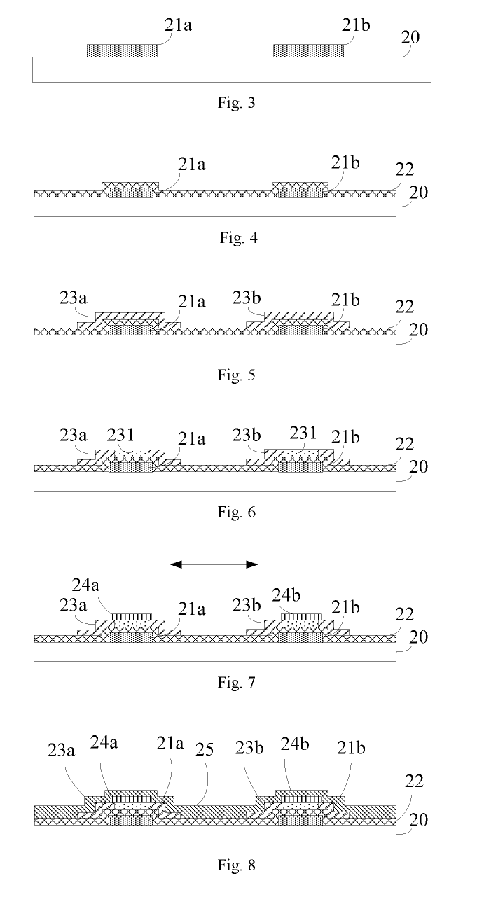

FIG. 2 is a flow chart of another method for manufacturing a complementary thin film transistor provided by an embodiment of the present disclosure. The method is suitable for manufacturing a complementary thin film transistor of a bottom gate type. The method for manufacturing the complementary TFT of a bottom gate type will be illustrated further with reference to FIGS. 3-13. As shown in FIG. 2, the method includes the following steps.

S201: a basal substrate is provided.

The basal substrate may be a transparent one, such as a glass substrate, a silicon substrate, a plastic substrate or the like. In S201, the substrate may be cleaned.

S202: a gate electrode layer pattern is formed on the basal substrate.

FIG. 3 is a structural schematic view of a basal substrate on which a gate electrode layer pattern is formed. As shown in FIG. 3, the gate electrode layer pattern includes a first gate electrode 21a and a second gate electrode 21b which are arranged at an interval.

Specifically, S202 may include: forming a gate electrode metal layer on the basal substrate, and forming the gate electrode layer pattern through a patterning process.

During implementation, the gate electrode metal layer may be formed on the basal substrate by sputtering. The gate electrode metal layer may be made of Al, Cu, Mo, Cr, Ti or the like, or an alloy comprising at least two of them.

S203: a gate electrode insulating layer is formed on the gate electrode layer pattern.

FIG. 4 is a structural schematic view after the gate electrode insulating layer 22 is formed. As shown in FIG. 4, the basal substrate 20 with gate electrode layer pattern is covered by the gate electrode insulating layer 22. During the implementation, a layer of insulating material may be formed by deposition on the basal substrate 20 with the gate electrode layer pattern so as to form the gate electrode insulating layer 22.

In some embodiments, the insulating material may be silicon nitride or silicon oxynitride.

S204: an active layer pattern is formed on the gate electrode insulating layer.

FIG. 5 is a structural schematic view after the active layer pattern is formed. As shown in FIG. 5, the active layer pattern may include a first active layer 23a and a second active layer 23b which are arranged in the same layer and at an interval. The first active layer 23a is disposed on the first gate electrode 21a, and the second active layer 23b is disposed on the second gate electrode 21b.

S204 may include: depositing a layer of active layer material on the gate electrode insulating layer, and forming the first active layer 23a and the second active layer 23b through a patterning process.

In some embodiments, the thickness of the first active layer 23a may be 400 Å˜600 Å, and the thickness of the second active layer 23b may be 400 Å-600 Å. The thickness of the first active layer 23a and the thickness of the second active layer 23b may be the same or different, and may be set based on the specific requirements.

During implementation, the first active layer 23a and the second active layer 23b may be manufactured by either amorphous silicon or polycrystalline silicon. Different active layer materials have different impact on the property of the complementary TFT. The materials of the first active layer 23a and the second active layer 23b may be selected based on the specific requirements. In the present embodiment, the active layer material is amorphous silicon.

In the present embodiment, the first active layer 23a and the second active layer 23b are made of the same material. In other embodiments, the first active layer 23a and the second active layer 23b may be made of different materials.

For example, when the first active layer 23a and the second active layer 23b are made of amorphous silicon, S204 may further include: annealing the first active layer to transform a portion of the first active layer into polycrystalline silicon; and annealing the second active layer to transform a portion of the second active layer into polycrystalline silicon.

In practice, the portion of the first active layer right above the first gate electrode (in a direction perpendicular to the basal substrate) may be annealed, so that the middle portion of the first active layer is annealed while two sides thereof are not annealed. Similarly, the portion of the second active layer right above the second gate electrode (in a direction perpendicular to the basal substrate) may be annealed, so that the middle portion of the second active layer is annealed while two sides thereof are not annealed.

The structures of the first active layer 23a and the second active layer 23b after the annealing treatment are shown in FIG. 6. The annealed area 231 of the first active layer 23a is right above the first gate electrode 21a, and the annealed area 231 of the second active layer 23b is right above the second gate electrode 21b.

The electron mobility in amorphous silicon is rather low, and is usually lower than 0.5 cm²V⁻¹S⁻¹. As a result, the response speed of the thin film transistor is quite low. The electron mobility in polycrystalline silicon can reach 200 cm²V⁻¹S⁻¹. By transforming amorphous silicon into polycrystalline silicon through annealing, the response speed of the thin film transistor can be greatly improved.

In practice, the first active layer or the second active layer may be annealed using an excimer laser. Low-temperature polycrystalline silicon may be formed by using the excimer laser. When performing annealing treatment using the excimer laser, the temperature is 500˜600° C., which is much lower than 1,000° C. in a traditional annealing process. Thus, substrates with low heat-resistance may be used for manufacturing to reduce the manufacturing cost.

S205: a barrier layer pattern is formed on the active layer pattern.

FIG. 7 is a structural schematic view after the barrier layer pattern is formed. As shown in FIG. 7, the barrier layer pattern may include a first barrier layer 24a and a second barrier layer 24b. The first barrier layer 24a is disposed on the first active layer 23a, and the orthographic projection of the first barrier layer 24a on the basal substrate 20 is within or completely overlaps with the orthographic projection of the first active layer 23a on the basal substrate 20. The second barrier layer 24b is disposed on the second active layer 23b, and the orthographic projection of the second barrier layer 24b on the basal substrate 20 is within or completely overlaps with the orthographic projection of the second active layer 23b on the basal substrate 20. The annealed areas of the first active layer 23a and the second active layer 23b can be protected by providing the first barrier layer 24a and the second barrier layer 24b, thereby preventing the first active layer 23a and the second active layer 23b from being damaged in the subsequent processes.

Further, the annealed area of the first active layer 23a is disposed within the orthographic projection of the first barrier layer 24a on the first active layer 23a, and the annealed area of the second active layer 23b is within or completely overlaps with the orthographic projection of the second barrier layer 24b on the second active layer 23b.

During implementation, S205 may include:

depositing a layer of barrier layer material on the active layer pattern, and

forming the first barrier layer 24a and the second barrier layer 24b through a patterning process.

In some embodiments, both the first barrier layer 24a and the second barrier layer 24b may be made of either SiNₓ or SiOₓ.

In some embodiments, the thickness of the first barrier layer 24a may be 1,000 Å˜2,000 Å, and the thickness of the second barrier layer 24b may be 1,000 Å-2,000 Å. If the first barrier layer 24a and the second barrier layer 24b are excessively thin, the first active layer 23a and the second active layer 23b cannot be effectively protected. If the first barrier layer 24a and the second barrier layer 24b are excessively thick, the thickness of the complementary thin film transistor will increase.

The width of the first barrier layer 24a in the direction in which the first active layer 23a and the second active layer 23b are disposed (i.e., the direction of the double-headed arrow in FIG. 7) may be 2 μm˜10 μm. The width of the second barrier layer 24b in the direction in which the first active layer 23a and the second active layer 23b are disposed may be 2 μm˜10 μm. The widths of the first barrier layer 24a and the second barrier layer 24b in the direction in which the first active layer 23a and the second active layer 23b are disposed may be set in accordance with the widths of the annealed area of the first active layer 23a and the annealed area of the second active layer 23b in the complementary thin film transistor in the direction in which the first active layer 23a and the second active layer 23b are disposed, so long as the first barrier layer 24a and the second barrier layer 24b can cover the annealed area of the first active layer 23a and the annealed area of the second active layer 23b. Since the annealed area of the first active layer 23a and the annealed area of the second active layer 23b correspond to a channel area where the thin film transistor operates, the channel area may be prevented from being damaged in the subsequent processes when covered with a barrier layer pattern.

S206: a first semiconductor material is deposited on the active layer pattern to form a first semiconductor layer.

FIG. 8 is a structural schematic view after the first semiconductor layer is formed. The first semiconductor layer 25 may be an N-type semiconductor layer.

The deposition method includes, but is not limited to, plasma enhanced chemical vapor deposition (PECVD).

When the N-type semiconductor material is deposited, SiH₄, PH₃ and H₂ may be introduced into a reaction chamber. The flow rate of SiH₄ may be 50˜200 sccm, the flow rate of PH₃ may be 10˜40 sccm, the flow rate of H₂ may be 200˜1000 sccm, and the deposition temperature may be 3500□˜410□.

S207: the first semiconductor layer is patterned to form a first ohmic contact layer.

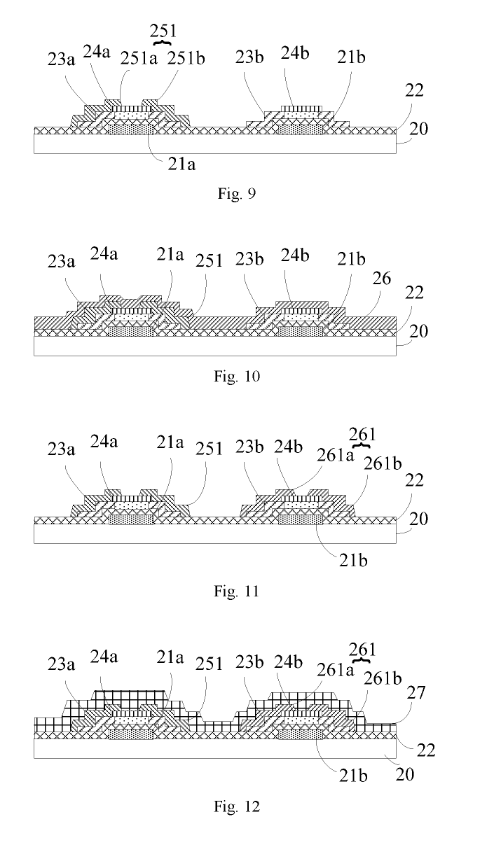

FIG. 9 is a structural schematic view after the first semiconductor layer is patterned. As shown in FIG. 9, the first ohmic contact layer 251 includes a first sub-layer 251a and a second sub-layer 251b which are separated from each other. Both the first sub-layer 251a and the second sub-layer 251b are disposed on the first active layer 23a. In addition, in a direction parallel to the basal substrate 20, the first barrier layer 24a is disposed between the first sub-layer 251a and the second sub-layer 251b. Both a portion of the first sub-layer 251a and a portion of the second sub-layer 251b are lapped to the first barrier layer 24a, and both another portion of the sub-layer 251a and another portion of the second sub-layer 251b are lapped to the first active layer 23a. Further, a portion of the first sub-layer 251a is lapped to one side edge of the first barrier layer 24a, and the other portion of the first sub-layer 251a covers a portion of the first active layer 23a that is not annealed. A portion of the second sub-layer 251b is lapped to the other side edge of the first barrier layer 24a, and the other portion of the second sub-layer 251b covers a portion of the first active layer 23a that is not annealed.

During implementation, the area of the first sub-layer 251a of the first ohmic contact layer 251 that right faces the annealed area on the first active layer 23a is larger than or equal to zero, and the area of the second sub-layer 251b of the first ohmic contact layer 251 that right faces the annealed area on the first active layer 23a is larger than or equal to zero. As a result, when a voltage is applied to the first gate electrode 21a, the first sub-layer 251a and the second sub-layer 251b of the first ohmic contact layer 251 can be electrically connected.

In some embodiments, the thickness of the first ohmic contact layer 251 may be 500 Å-1,000 Å.

S208: a second semiconductor material is deposited on the active layer pattern to form a second semiconductor layer.

FIG. 10 is a structural schematic view after the second semiconductor layer is formed. During implementation, the second semiconductor layer 26 may be a P-type semiconductor layer.

The deposition method includes, but is not limited to PECVD.

When the P-type semiconductor material is deposited, SiH₄, B₂H₆ and H₂ may be introduced into a reaction chamber. The flow rate of SiH₄ may be 50˜200 sccm, the flow rate of B₂H₆ may be 20˜60 sccm, the flow rate of H₂ may be 200˜1000 sccm, and the deposition temperature may be 270□˜320□.

S209: the second semiconductor layer is patterned to form a second ohmic contact layer.

FIG. 11 is a structural schematic view after the second semiconductor layer is patterned. As shown in FIG. 11, the second ohmic contact layer 261 includes a first sub-layer 261a and a second sub-layer 261b which are separated from each other. Both the first sub-layer 261a and the second sub-layer 261b are disposed on the second active layer 23b. In addition, in a direction parallel to the basal substrate 20, the second barrier layer 24b is disposed between the first sub-layer 261a and the second sub-layer 261b. Both a portion of the first sub-layer 261a and a portion of the second sub-layer 261b are lapped to the second barrier layer 24b, and both another portion of the first sub-layer 261a and another portion of the second sub-layer 261b are lapped to the second active layer 23b. That is to say, a portion of the first sub-layer 261a is lapped to one side edge of the second barrier layer 24b, and the other portion of the first sub-layer 261a covers a portion of the second active layer 23b that is not annealed A portion of the second sub-layer 261b is lapped to the other side edge of the second barrier layer 24b, and the other portion of the second sub-layer 261b covers a portion of the second active layer 23b that is not annealed.

During implementation, the area of the first sub-layer 261a of the second ohmic contact layer 261 that right faces the annealed area on the second active layer 23b is larger than or equal to zero, and the area of the second sub-layer 261b of the second ohmic contact layer 261 that right faces the annealed area on the second active layer 23b is larger than or equal to zero. As a result, when a voltage is applied to the second gate electrode 21b, the first sub-layer 261a and the second sub-layer 261b of the second ohmic contact layer 261 can be electrically connected.

In some embodiments, the thickness of the second ohmic contact layer 261 may be 500 Å-1,000 Å.

The first semiconductor layer and the second semiconductor layer are directly formed by deposition, and doping is not needed, which can be beneficial to reduce the production difficulty and improve the production efficiency, and at the same time facilitate the production of array substrates of large sizes, for example, an array substrate with a size of G8.

It should be noted that, when the above-mentioned steps are performed, S206 and S207 may be performed first, followed by S208 and S209. Alternatively, S208 and S209 may be performed first, followed by S206 and S207. That is to say, the P-type semiconductor layer may be formed after the N-type semiconductor layer is formed, or the N-type semiconductor layer may be formed after the P-type semiconductor layer is formed, which is not limited in the present disclosure.

S210: a source-drain electrode pattern is formed on the first ohmic contact layer and the second ohmic contact layer.

The source-drain electrode pattern includes a first source electrode, a first drain electrode, a second source electrode and a second drain electrode. The first source electrode and the first drain electrode are connected to the first ohmic contact layer, and the second source electrode and the second drain electrode are connected to the second ohmic contact layer. The first source electrode, the first drain electrode, the second source electrode and the second drain electrode are manufactured to form various electrodes of the complementary thin film transistor for subsequent connection with other circuits.

During implementation, S210 may include: forming a source-drain electrode metal layer on the first ohmic contact layer and the second ohmic contact layer, and patterning the source-drain electrode metal layer to form the first source electrode, the first drain electrode, the second source electrode and the second drain electrode.

It should be noted that, based on different application scenarios of the complementary thin film transistor, the first drain electrode and the second source electrode may be or may not be connected (in this case, in a direction parallel to the basal substrate, the first drain electrode and the second source electrode are disposed between the second drain electrode and the first source electrode). Alternatively, the first source electrode and the second drain electrode may be or may not be connected (in this case, in the direction parallel to the basal substrate, the second drain electrode and the first source electrode are disposed between the first drain electrode and the second source electrode).

In some embodiments, the source-drain electrode metal layer may be made of Al, Cu, Mo, Cr, Ti or the like, or an alloy comprising at least two of them. Specifically, the source-drain electrode metal layer may be manufactured by sputtering.

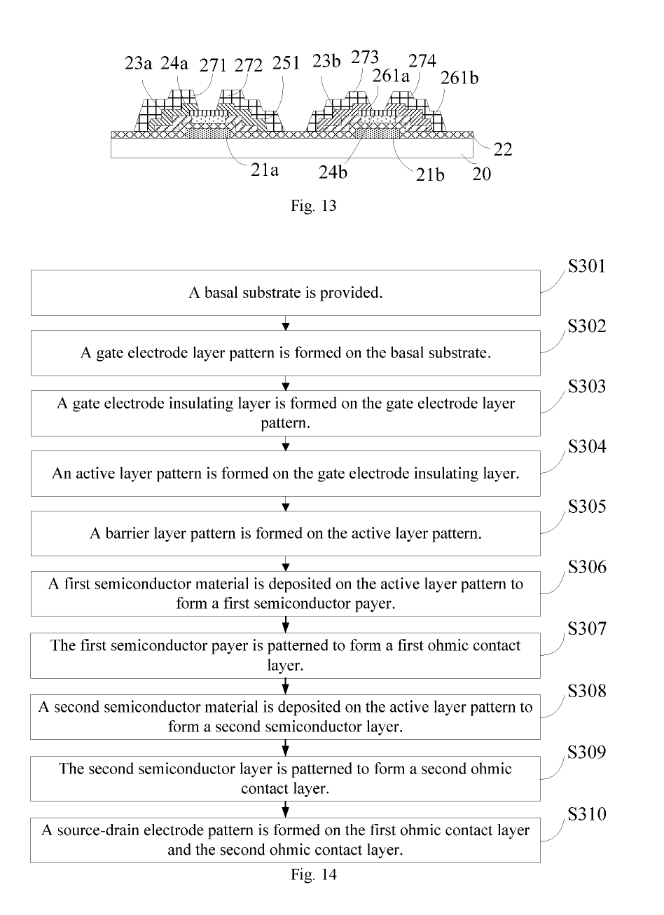

The structure after the source-drain electrode metal layer is formed on the first ohmic contact layer and the second ohmic contact layer may be referenced to FIG. 12, and the structure after the patterning process may be referenced to FIG. 13.

As shown in FIG. 12, the source-drain electrode metal layer 271 covers the first ohmic contact layer 251 and the second ohmic contact layer 261. As shown in FIG. 13, the first source electrode 271 and the first drain electrode 272 cover the first ohmic contact layer 251, and the second source electrode 273 and the second drain electrode 274 cover the second ohmic contact layer 261. Therefore, the contact area between the first source electrode 271 and the first ohmic contact layer 251 and the contact area between the first drain electrode 272 and the first ohmic contact layer 251 may increase, which is beneficial to reduce the contact resistance between the first source electrode 271 and the first ohmic contact layer 251 and the contact resistance between the first drain electrode 272 and the first ohmic contact layer 251. The contact area between the second source electrode 273 and the second ohmic contact layer 261 and the contact area between the second drain electrode 274 and the second ohmic contact layer 261 may increase, which is beneficial to reduce the contact resistance between the second source electrode 273 and the second ohmic contact layer 261 and the contact resistance between the second drain electrode 274 and the second ohmic contact layer 261.

It should be noted that FIG. 13 is merely an example. In other embodiments, the relative position between the first source electrode 271 and the first drain electrode 272, and the relative position between the second source electrode 273 and the second drain electrode 274 in FIG. 13 may be exchanged. For example, 271 may also be the first drain electrode, and 272 may also be the first source electrode.

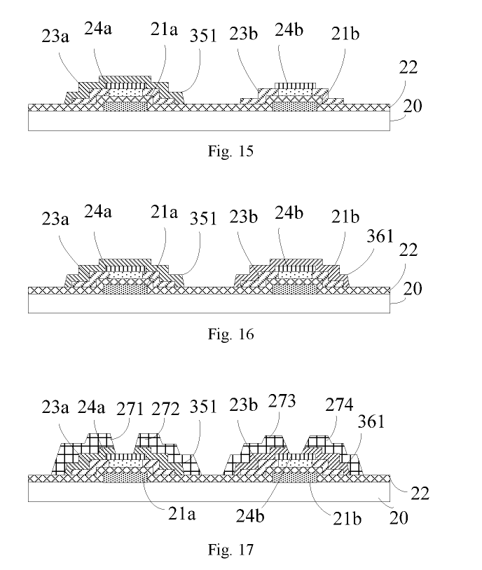

FIG. 14 is a flow chart of another method for a manufacturing a complementary thin film transistor provided by an embodiment of the present disclosure. The method is suitable for manufacturing the complementary thin film transistor of a bottom gate type. The method shown in FIG. 14 differs from the method shown in FIG. 13 in that: in the method shown in FIG. 14, during the process of manufacturing the source electrodes and the drain electrodes through a patterning process, the first ohmic contact layer is manufactured into the first sub-layer and the second sub-layer which are independent, and the second ohmic contact layer is also manufactured into the first sub-layer and the second sub-layer which are independent. The followings will further explain the method for manufacturing the complementary thin film transistor of a bottom gate type with reference to FIGS. 15-17. As shown in FIG. 14, the method includes the following steps.

Step 301: a basal substrate is provided.

The implementation method of S301 is the same as that of S201, which is not repeated here.

S302: a gate electrode layer pattern is formed on the basal substrate.

The implementation method of S302 is the same as that of S202, which is not repeated here.

S303: a gate electrode insulating layer is formed on the gate electrode layer pattern.

The implementation method of S303 is the same as that of S203, which is not repeated here.

S304: an active layer pattern is formed on the gate electrode insulating layer.

The implementation method of S304 is the same as that of S204, which is not repeated here.

S305: a barrier layer pattern is formed on the active layer pattern.

The implementation method of S305 is the same as that of S205, which is not repeated here.

S306: a first semiconductor material is deposited on the active layer pattern to form a first semiconductor payer.

The implementation method of S306 is the same as that of S206, which is not repeated here.

S307: the first semiconductor payer is patterned to form a first ohmic contact layer.

FIG. 15 is a structural schematic view after the first ohmic contact layer is formed. As shown in FIG. 15, the first ohmic contact layer 351 covers the first active layer 23a and the first barrier layer 24a. The first ohmic contact layer 351 shown in FIG. 15 differs from the first ohmic contact layer 251 shown in FIG. 9 in that: the first ohmic contact layer 351 shown in FIG. 15 is of an integral structure.

S308: a second semiconductor material is deposited on the active layer pattern to form a second semiconductor layer.

The implementation method of S308 may be the same as that of S208, and will not be repeated here again.

S309: the second semiconductor layer is patterned to form a second ohmic contact layer.

FIG. 16 is a structural schematic view after the second ohmic contact layer is formed. As shown in FIG. 16, the second ohmic contact layer 361 covers the second active layer 23b and the second barrier layer 24b. The second ohmic contact layer 361 shown in FIG. 16 differs from the second ohmic contact layer 261 shown in FIG. 11 in that: the second ohmic contact layer 361 shown in FIG. 16 is of an integral structure.

S310: a source-drain electrode pattern is formed on the first ohmic contact layer and the second ohmic contact layer.

During implementation, S310 may include: forming a source-drain electrode metal layer on the first ohmic contact layer and the second ohmic contact layer, and patterning the source-drain electrode metal layer, the first ohmic contact layer and the second ohmic contact layer.

FIG. 17 is a structural schematic view after the source-drain electrode pattern is formed. As shown in FIG. 17, the source-drain electrode metal layer, the first ohmic contact layer 351 and the second ohmic contact layer 361 are patterned so that the first source electrode 271, the first drain electrode 272, the second source electrode 273 and the second drain electrode 274 are formed, the first ohmic contact layer 351 is divided into a first sub-layer and a second sub-layer which are separated from each other, and the second ohmic contact layer 361 is divided into a first sub-layer and a second sub-layer which are separated from each other. The first source electrode 271 is disposed on the first sub-layer of the first ohmic contact layer 351. The first drain electrode 272 is disposed on the second sub-layer of the first ohmic contact layer 351. The second source electrode 273 is disposed on the first sub-layer of the second ohmic contact layer 361. The second drain electrode 274 is disposed on the second sub-layer of the second ohmic contact layer 361.

In an implementation method of the present disclosure, the source-drain electrode metal layer, the first ohmic contact layer and the second ohmic contact layer may be treated at the same time by one patterning process.

In another implementation method of the present disclosure, two patterning processes may be performed. For example, the source-drain electrode metal layer may be patterned once at first to form a first electrode layer covering the first ohmic contact layer and a second electrode layer covering the second ohmic contact layer. Then, the first electrode layer and the first ohmic contact layer, and the second electrode layer and the second ohmic contact layer may be patterned so that the first source electrode, the first drain electrode, the second source electrode and the second drain electrode are formed, the first ohmic contact layer is divided into a first sub-layer and a second sub-layer which are separated from each other, and the second ohmic contact layer is divided into a first sub-layer and a second sub-layer which are separated from each other.

In the method shown in FIGS. 14 to 17, the first ohmic contact layer, the second ohmic contact layer, the first source electrode, the first drain electrode, the second source electrode and the second drain electrode are manufactured at the same time through the patterning process. Compared to the manner of etching in two steps, the pattern alignment steps are reduced and the manufacturing process is simplified, which facilitates to improve the manufacturing efficiency.

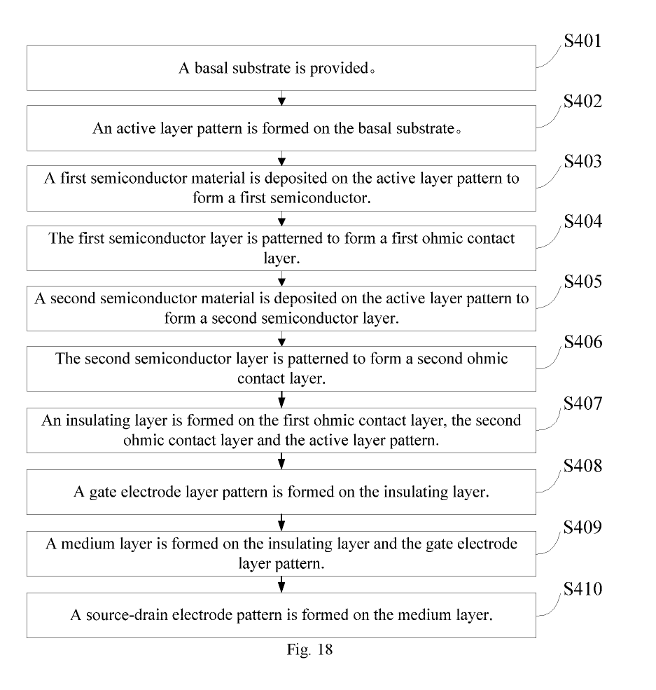

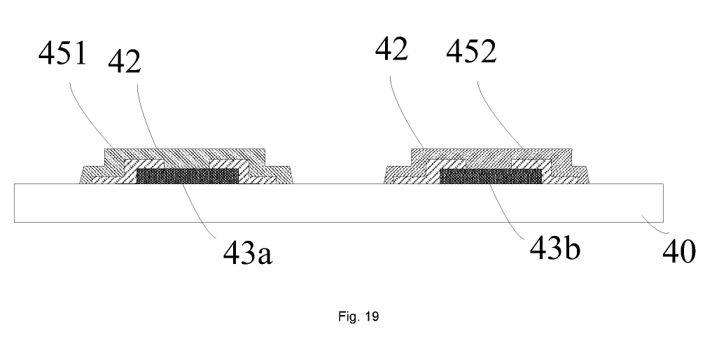

FIG. 18 is a flow chart of another method for manufacturing a complementary thin film transistor provided by an embodiment of the present disclosure. The method is suitable for manufacturing the complementary thin film transistor of a top gate type. The followings will further explain the method for manufacturing the complementary thin film transistor of a top gate type with reference to FIGS. 19-22. As shown in FIG. 18, the method includes the following steps.

S401: a basal substrate is provided.

The implementation method of S401 is the same as that of S201, which is not repeated here.

S402: an active layer pattern is formed on the basal substrate.

The implementation method of S402 is the same as that of S204, which is not repeated here.

S403: a first semiconductor material is deposited on the active layer pattern to form a first semiconductor layer.

The implementation method of S403 is the same as that of S206, which is not repeated here.

S404: the first semiconductor layer is patterned to form a first ohmic contact layer.

The implementation method of S404 is the same as that of S207, which is not repeated here.

S405: a second semiconductor material is deposited on the active layer pattern to form a second semiconductor layer.

The implementation method of S405 is the same as that of S208, which is not repeated here.

S406: the second semiconductor layer is patterned to form a second ohmic contact layer.

The implementation method of S406 is the same as that of S209, which is not repeated here.

S407: an insulating layer is formed on the first ohmic contact layer, the second ohmic contact layer and the active layer pattern.

FIG. 19 is a structural schematic view after the insulating layer is formed. As shown in FIG. 19, the active layer pattern includes a first active layer 43a and a second active layer 43b which are arranged on the basal substrate 40 at an interval. The first ohmic contact layer 451 is formed on the first active layer 43a, and the second ohmic contact layer 452 is formed on the second active layer 43b. The first active layer 43a and the first ohmic contact layer 451, and the second active layer 43b and the second ohmic contact layer 452 are all covered by an insulating material. During implementation, a layer of insulating material may be formed by deposition on the basal substrate 40, the first ohmic contact layer 451, the second ohmic contact layer 452, the first active layer 43a and the second active layer 43b to form an insulating layer 42. The insulating layer 42 is then treated through a patterning process.

In some embodiments, the insulating material may be silicon nitride or silicon oxynitride.

S408: a gate electrode layer pattern is formed on the insulating layer.

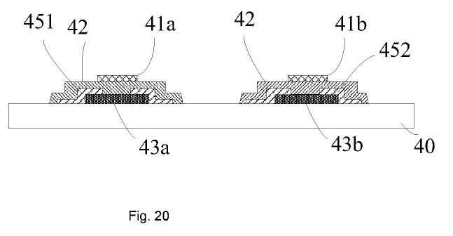

FIG. 20 is a structural schematic view after the gate electrode layer pattern is formed. As shown in FIG. 20, the gate electrode layer pattern includes a first gate electrode 41a and a second gate electrode 41b which are disposed at an interval.

It should be noted that, if the first active layer 43a and the second active layer 43b are annealed in step S402, in a direction perpendicular to the basal substrate 40, the first gate electrode 41a right faces the annealed area of the first active layer 43a. That is, the annealed area of the first active layer 43a is disposed right below the first gate electrode 41a. The second gate electrode 41b right faces the annealed area of the second active layer 43b. That is, the annealed area of the second active layer 43b is disposed right below the second gate electrode 41b.

Specifically, S408 may include: forming a gate electrode metal layer on the insulating layer; and patterning the gate electrode metal layer to form a gate electrode layer pattern.

During implementation, the gate electrode metal layer may be formed on the insulating layer by sputtering. The gate electrode metal layer may be made of Al, Cu, Mo, Cr, Ti or the like, or an alloy comprising at least two of them.

S409: a medium layer is formed on the insulating layer and the gate electrode layer pattern.

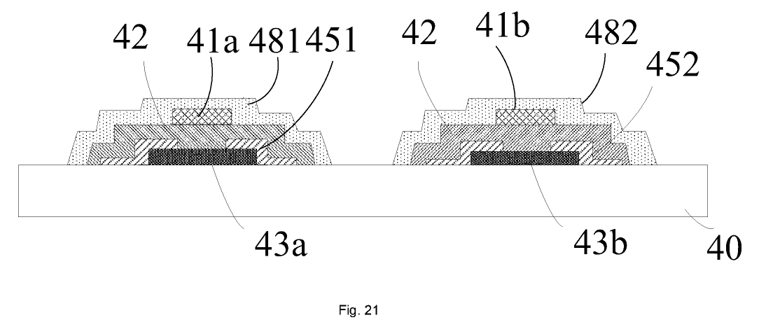

The structure after the medium layer may is formed may be referenced to FIG. 21. As shown in FIG. 21, the medium layer includes a first medium layer 481 and a second medium layer 482 which are arranged at an interval. The first medium layer 481 covers the first gate electrode 41a, and the second medium layer 482 covers the second gate electrode 41b.

In some embodiments, the medium layer may be a silicon nitride layer or a silicon oxynitride layer. During implementation, the medium layer may be formed by sputtering and then treated through a patterning process to obtain the first medium layer and the second medium layer.

S410: a source-drain electrode pattern is formed on the medium layer.

For example, step S410 may include: forming a via hole in the medium layer and on the insulating layer. The via hole extends from the medium layer to the first ohmic contact layer and the second ohmic contact layer; and forming the source-drain electrode pattern that connects the first ohmic contact layer and the second ohmic contact layer on the medium layer.

The structure after the source-drain electrode pattern is formed may be referenced to FIG. 21. As shown in FIG. 21, the source-drain electrode pattern may include a first source electrode 491, a first drain electrode 492, a second source electrode 493 and a second drain electrode 494. The first source electrode 491 and the first drain electrode 492 are respectively connected to the first ohmic contact layer 451 through via holes, and the second source electrode 493 and the second drain electrode 494 are respectively connected to the second ohmic contact layer 452 through via holes. The first source electrode 491, the first drain electrode 492, the second source electrode 493 and the second drain electrode 494 are manufactured to form various electrodes of the complementary thin film transistor to facilitate the connection. In a direction parallel to the basal substrate 40, the first gate electrode 41a is disposed between the first source electrode 491 and the first drain electrode 492, and the second gate electrode 41b is disposed between the second source electrode 493 and the second drain electrode 494.

In some embodiments, before step S402, the method may further include: forming a light shielding layer pattern on the basal substrate.

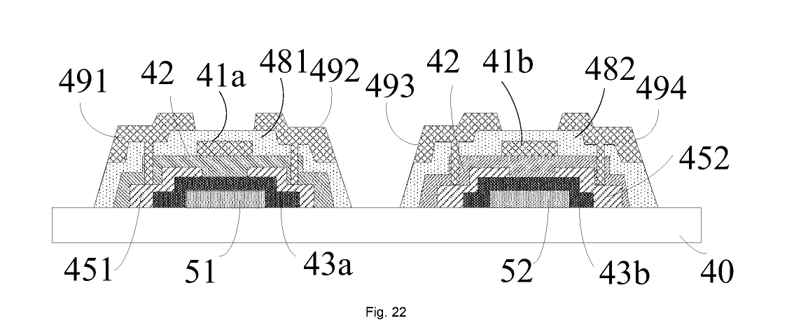

For example, FIG. 22 is a structural schematic view of a complementary thin film transistor in which a light shielding layer pattern is formed. As shown in FIG. 22, the light shielding layer pattern may include a first light shielding layer 51 and a second light shielding layer 52. The first light shielding layer 51 and the second light shielding layer 52 may shield light, so as to prevent the light from irradiating the first active layer 43a and the second active layer 43b formed in the followed steps from the back of the basal substrate 40 to further impact the performance of the thin film transistor.

An embodiment of the present disclosure further provides a complementary thin film transistor. The complementary thin film transistor includes an active layer pattern, a first ohmic contact layer and a second ohmic contact layer. The active layer pattern includes a first active layer and a second active layer which are disposed in the same layer at an interval. The first ohmic contact layer is disposed on the first active layer, and the second ohmic contact layer is disposed on the second active layer.

In an implementation method of the disclosure, the complementary thin film transistor is a complementary thin film transistor of a bottom gate type and the structure thereof may be referenced to FIG. 13. The complementary thin film transistor of a bottom gate type may further include a first gate electrode 21 and a second gate electrode 21b which are disposed on the basal substrate 20, and a gate electrode insulating layer 22 laminated on the first gate electrode 21a and the second gate electrode 21b. The active layer pattern is disposed on the gate electrode insulating layer 22. The first active layer 23a is disposed right above the first gate electrode 21a, and the second active layer 23b is disposed right above the second gate electrode 21b. A first source electrode 271 and a first drain electrode 272 are also disposed on the first ohmic contact layer 251, and a second source electrode 273 and a second drain electrode 274 are also disposed on the second ohmic contact layer 261. The complementary thin film transistor may be manufactured by adopting the method shown in FIGS. 2 to 13, or the method shown in FIGS. 14 to 17.

In another implementation of the disclosure, the complementary thin film transistor is a complementary thin film transistor of a top gate type, and the structure thereof may be referenced to FIG. 22. The complementary thin film transistor of a top gate type may further include a first light shielding layer 51 and a second light shielding layer 52 which are disposed on a basal substrate 40 in the same layer at an interval. A first active layer 43a is laminated on the first light shielding layer 51, and a second active layer 43b is laminated on the second light shielding layer 52. An insulating layer 42 is further disposed on the first ohmic contact layer 451, the first active layer 43a, the second ohmic contact layer 452 and the second active layer 43b. Both the first gate electrode 41a and the second gate electrode 41b are disposed on the insulating layer 42. The first gate electrode 41a is disposed right above the first active layer 43a, and the second gate electrode 41b is disposed right above the second active layer 43b. A medium layer 481 is further disposed on the surface of the first gate electrode 41a and a medium layer 482 is further disposed on the surface of the second gate electrode 41b. A first source electrode 491 and a first drain electrode 492 are further disposed on the medium layer 481, and a second source electrode 493 and a second drain electrode 494 are further disposed on the medium layer 482. The first source electrode 491 and the first drain electrode 492 are connected to the first ohmic contact layer 451 through via holes. The second source electrode 493 and the second drain electrode 494 are connected to the second ohmic contact layer 452 through via holes. The complementary thin film transistor may be manufactured by adopting the method shown in FIGS. 18 to 22.

It should be noted that, in the complementary thin film transistor of a top gate type shown in FIG. 22, the first light shielding layer and the second light shielding layer may also not be provided.

During the process of manufacturing the complementary thin film transistor in the embodiments of the present disclosure, a first semiconductor layer is formed on the active layer pattern and the first semiconductor layer is patterned to form the first ohmic contact layer. In addition, a second semiconductor layer is formed on the active layer pattern and the second semiconductor layer is patterned to form the second ohmic contact layer. Since one of the first semiconductor layer and the second semiconductor layer is an N-type semiconductor layer and the other is a P-type semiconductor layer, doping is not needed and thus the manufacturing cost of the CMOS TFT may be reduced.

The embodiments of the present disclosure further provide an array substrate. The array substrate includes the complementary thin film transistor described above.

During the process of manufacturing the complementary thin film transistor in the embodiments of the present disclosure, a first semiconductor layer is formed on the active layer pattern and the first semiconductor layer is patterned to form the first ohmic contact layer. In addition, a second semiconductor layer is formed on the active layer pattern and the second semiconductor layer is patterned to form the second ohmic contact layer. Since one of the first semiconductor layer and the second semiconductor layer is an N-type semiconductor layer and the other is a P-type semiconductor layer, doping is not needed and thus the manufacturing cost of the CMOS TFT may be reduced.

The foregoing are only some embodiments of the present disclosure, and are not intended to limit the present disclosure. Within the spirit and principles of the disclosure, any modifications, equivalent substitutions, improvements, etc., are within the scope of protection of the present disclosure.

What is claimed is:

1. A method for manufacturing a complementary thin film transistor, comprising:
forming a first semiconductor layer on an active layer pattern, and patterning the first semiconductor layer to form a first ohmic contact layer on a first active layer, the active layer pattern comprising the first active layer and a second active layer which are arranged in the same layer at an interval;
forming a second semiconductor layer on the active layer pattern, and patterning the second semiconductor layer to form a second ohmic contact layer on the second active layer,
wherein one of the first semiconductor layer and second semiconductor layer is an N-type semiconductor layer, and the other is a P-type semiconductor layer.

2. The method for manufacturing a complementary thin film transistor according to claim 1, wherein
before forming the first semiconductor layer on the active layer pattern and forming the second semiconductor layer on the active layer pattern, the method further comprises:
forming a gate electrode layer pattern on a basal substrate, the gate electrode layer pattern comprising a first gate electrode and a second electrode arranged at an interval;
forming a gate electrode insulating layer on the gate electrode layer pattern; and
forming the active layer pattern on the gate electrode insulating layer, the first active layer being disposed on the first gate electrode and the second active layer being disposed on the second gate electrode.

3. The method for manufacturing a complementary thin film transistor according to claim 2, wherein
after forming the active layer pattern on the gate electrode insulating layer, the method further comprises:
forming a barrier layer pattern on the active layer pattern, wherein the barrier layer pattern includes a first barrier layer and a second barrier layer, the first barrier layer is disposed on the first active layer, the orthographic projection of the first barrier layer on the basal substrate is within or completely overlaps with the orthographic projection of the first active layer on the basal substrate, the second barrier layer is disposed on the second active layer, and the orthographic projection of the second barrier layer on the basal substrate is within or completely overlaps with the orthographic projection of the second active layer on the basal substrate.

4. The method for manufacturing a complementary thin film transistor according to claim 3, wherein the thickness of the first barrier layer is 1,000-2,000 angstrom, and the thickness of the second barrier layer is 1,000-2,000 angstrom.

5. The method for manufacturing a complementary thin film transistor according to claim 1, further comprising:
forming a source-drain electrode pattern on the first ohmic contact layer and second ohmic contact layer, wherein the source-drain electrode pattern includes a first source electrode, a first drain electrode, a second source electrode and a second drain electrode, the first source electrode and the first drain electrode are respectively connected to the first ohmic contact layer, and the second source electrode and the second drain electrode are respectively connected to the second ohmic contact layer.

6. The method for manufacturing a complementary thin film transistor according to claim 5, wherein forming the source-drain electrode pattern on the first ohmic contact layer and second ohmic contact layer includes:
forming a source-drain electrode metal layer on the first ohmic contact layer and second ohmic contact layer; and
patterning the source-drain electrode metal layer, the first ohmic contact layer and the second ohmic contact layer so that the first source electrode, the first drain electrode, the second source electrode and the second drain electrode are formed, the first ohmic contact layer is divided into a first sub-layer and a second sub-layer which are separated from each other, and the second ohmic contact layer is divided into a first sub-layer and a second sub-layer which are separated from each other, wherein the first source electrode is disposed on the first sub-layer of the first ohmic contact layer, the first drain electrode is disposed on the second sub-layer of the first ohmic contact layer, the second source electrode is disposed on the first sub-layer of the second ohmic contact layer, and the second drain electrode is disposed on the second sub-layer of the second ohmic contact layer.

7. The method for manufacturing a complementary thin film transistor according to claim 1, further comprising:
forming an insulating layer on the first ohmic contact layer, the second ohmic contact layer and the active layer pattern; and
forming a gate electrode layer pattern and a source-drain electrode pattern on the insulating layer, wherein the gate electrode layer pattern includes a first gate electrode and a second gate electrode which are arranged at an interval, the source-drain electrode pattern includes a first source electrode, a first drain electrode, a second source electrode and a second drain electrode, the first source electrode and the first drain electrode are respectively connected to the first ohmic contact layer, and the second source electrode and the second drain electrode are respectively connected to the second ohmic contact layer.

8. The method for manufacturing a complementary thin film transistor according to claim 7, wherein forming the gate electrode layer pattern and the source-drain electrode pattern on the insulating layer includes:
forming the gate electrode layer pattern on the insulating layer;
forming a medium layer on the insulating layer and the gate electrode layer pattern; and
forming the source-drain electrode pattern on the medium layer.

9. The method for manufacturing a complementary thin film transistor according to claim 7, wherein
before forming the first semiconductor layer on the active layer pattern and forming the second semiconductor layer on the active layer pattern, the method further comprises:
forming a light shielding layer pattern on the basal substrate, the light shielding layer pattern comprising a first light shielding layer and a second light shielding layer which are arranged at an interval; and
forming the active layer pattern on the light shielding layer pattern, the first active layer being disposed on the first light shielding layer and the second active layer being disposed on the second light shielding layer.

10. The method for manufacturing a complementary thin film transistor according to claim 1, wherein the first active layer and the second active layer are respectively made of any of: amorphous silicon and polycrystalline silicon.

11. The method for manufacturing a complementary thin film transistor according to claim 1, wherein when both of the first active layer and the second active layer are made of amorphous silicon, the method further comprises:
annealing the first active layer so that a portion of the first active layer is transformed into polycrystalline silicon, and the first ohmic contact layer is connected to the portion of the first active layer that is not annealed; and
annealing the second active layer so that a portion of the second active layer is transformed into polycrystalline silicon, and the second ohmic contact layer is connected to the portion of the second active layer that is not annealed.

12. The method for manufacturing a complementary thin film transistor according to claim 11, wherein
annealing the first active layer includes: annealing the portion of the first active layer that right faces the first gate electrode in a direction perpendicular to the basal substrate; and
annealing the second active layer includes: annealing the portion of the second active layer that right faces the second gate electrode in a direction perpendicular to the basal substrate.

13. The method for manufacturing a complementary thin film transistor according to claim 9, wherein annealing of the first active layer or the second active layer is performed using excimer laser.

14. The method for manufacturing a complementary thin film transistor according to claim 1, wherein forming the first semiconductor layer on the active layer pattern includes: when the first semiconductor layer is an N-type semiconductor layer, depositing a first semiconductor material on the active layer pattern using SiH4, PH3 and H2 to form the first semiconductor layer; and
forming the second semiconductor layer on the active layer pattern includes: when the second semiconductor layer is a P-type semiconductor layer, depositing a second semiconductor material on the active layer pattern using SiH4, B2H6 and H2 to form the second semiconductor layer.

15. The method for manufacturing a complementary thin film transistor according to claim 1, wherein forming the first semiconductor layer on the active layer pattern includes: when the first semiconductor layer is a P-type semiconductor layer, depositing a first semiconductor material on the active layer pattern using SiH4, B2H6 and H2 to form the first semiconductor layer; and
forming the second semiconductor layer on the active layer pattern includes: when the second semiconductor layer is an N-type semiconductor layer, depositing a second semiconductor material on the active layer pattern using SiH4, PH3 and H2 to form the second semiconductor layer.

16. The method for manufacturing a complementary thin film transistor according to claim 1, wherein the thickness of the first active layer is 400-600 angstrom, and the thickness of the second active layer is 400-600 angstrom.

17. The method for manufacturing a complementary thin film transistor according to claim 1, wherein the thickness of the first ohmic contact layer is 500-1,000 angstrom, and the thickness of the second ohmic contact layer is 500-1,000 angstrom.

18. A complementary thin film transistor, comprising an active layer pattern, a first ohmic contact layer and a second ohmic contact layer, wherein the active layer pattern includes a first active layer and a second active layer which are arranged in the same layer at an interval, the first ohmic contact layer is disposed on the first active layer, and the second ohmic contact layer is disposed on the second active layer.

19. The complementary thin film transistor according to claim 18, wherein the complementary thin film transistor is of a top gate type or a bottom gate type.

20. An array substrate comprising a complementary thin film transistor, wherein the complementary thin film transistor includes an active layer pattern, a first ohmic contact layer and a second ohmic contact layer, the active layer pattern includes a first active layer and a second active layer which are arranged in the same layer at an interval, the first ohmic contact layer is disposed on the first active layer, and the second ohmic contact layer is disposed on the second active layer.
